(19) United States
(12) Patent Application Publication
(10) Pub. No.: US 2026/0059857 A1
(43) Pub. Date: Feb. 26, 2026

(54) SEMICONDUCTOR DEVICE AND METHOD FOR MANUFACTURING THE SAME

(71) Applicant: Samsung Electronics Co., Ltd., Suwon-si (KR)

(72) Inventors: Yoonbeom PARK, Suwon-si (KR); Hidenobu FUKUTOME, Suwon-si (KR); Jinkyu KIM, Suwon-si (KR); Yunsuk NAM, Suwon-si (KR); Jaehoon SHIN, Suwon-si (KR); Inho YEO, Suwon-si (KR); Yongwoo LEE, Suwon-si (KR)

(73) Assignee: Samsung Electronics Co., Ltd., Suwon-si (KR)

(21) Appl. No.: 19/072,208

(22) Filed: Mar. 6, 2025

(30) Foreign Application Priority Data
Aug. 22, 2024 (KR) 10-2024-0112992

(51) Int. Cl. H10D 84/90

(52) U.S. Cl. CPC H10D 84/966; H10D 84/953

(57) ABSTRACT

A semiconductor device may include a first impurity pattern and a second impurity pattern spaced apart from each other in a first direction on a substrate, where the first direction may be parallel to an upper surface of the substrate and where the first and second impurity patterns may include impurities having different conductive types; a first semiconductor pattern between the first impurity pattern and the second impurity pattern; and a first gate pattern crossing the first semiconductor pattern. The first gate pattern may include a gate region and an extension region. The gate region may extend in a second direction, which may cross the first direction. The extension region may extend from the gate region in the first direction.

### CROSS-REFERENCE TO RELATED APPLICATIONS

This U.S. non-provisional patent application claims priority under 35 U.S.C. § 119 of Korean Patent Application No. 10-2024-0112992, filed on Aug. 22, 2024, the entire contents of which are hereby incorporated by reference.

### BACKGROUND

The present disclosure herein relates to a semiconductor device and/or a method for manufacturing the same, and more particularly, to a semiconductor device including a field effect transistor and/or a method for manufacturing the same.

A semiconductor device may include an integrated circuit having of metal-oxide-semiconductor field effect transistors (MOSFET). As a size and a design rule of the semiconductor device are gradually decreasing, scaling down of the metal-oxide-semiconductor field effect transistors is also gradually being accelerated. As the metal-oxide-semiconductor field effect transistors are gradually scaled down, operation characteristics of the semiconductor device may deteriorate. Accordingly, research on various methods for overcoming limitation caused by high-integration of the semiconductor device and/or forming the semiconductor device with improved performance is being conducted.

### SUMMARY

The present disclosure provides a semiconductor device with improved electrical characteristics and/or a method for manufacturing the same.

The present disclosure also provides a semiconductor device with improved productivity and/or integration and/or a method for manufacturing the same.

Aspects of inventive concepts are not limited to those mentioned above, and other technical aspects that are not mentioned may be understood from description below by those skilled in the art.

According to an embodiment of inventive concepts, a semiconductor device may include a first impurity pattern and a second impurity pattern spaced apart from each other in a first direction on a substrate, the first direction being parallel to an upper surface of the substrate, and the first impurity pattern including impurities of a different conductive type than impurities in the second impurity pattern; a first semiconductor pattern between the first impurity pattern and the second impurity pattern; and a first gate pattern crossing the first semiconductor pattern. The first gate pattern may include a gate region extends in a second direction and an extension region extending from the gate region in the first direction. The second direction may cross the first direction.

According to an embodiment of inventive concepts, a semiconductor device may include a first impurity pattern and a second impurity pattern spaced apart from each other in a first direction on a substrate, the first direction being parallel to an upper surface of the substrate, the first impurity pattern including impurities of a different conductive type than impurities in the second impurity pattern; a first semiconductor pattern between the first impurity pattern and the second impurity pattern; and a first gate pattern crossing the first semiconductor pattern. The first gate pattern may include gate regions adjacent to each other in the first direction. Each of the gate regions may extend in a second direction. The second direction may cross the first direction. The first gate pattern may further includes an extension region between the gate regions of the first gate pattern.

According to an embodiment of inventive concepts, a semiconductor device may include a first impurity pattern and a second impurity pattern spaced apart from each other in a first direction on a substrate, the first direction being parallel to an upper surface of the substrate, and the first impurity pattern including impurities of a different conductive type than impurities in the second impurity pattern; a first semiconductor pattern between the first impurity pattern and the second impurity pattern; a second semiconductor pattern spaced apart from the first semiconductor pattern with the first impurity pattern therebetween, each of the first semiconductor pattern and the second semiconductor pattern including a plurality of semiconductor layers stacked on the substrate; a first gate pattern crossing the first semiconductor pattern; a second gate pattern crossing the second semiconductor pattern; an internal gate spacer between the first impurity pattern and the first gate pattern; and a rear surface active contact under at least one of the first impurity pattern or the second impurity pattern. The first gate pattern may include gate regions and an extension region between the gate regions. The gate regions may be adjacent to each other in the first direction. Each of the gate regions may extend in a second direction. The second direction may cross the first direction.

### BRIEF DESCRIPTION OF THE FIGURES

The accompanying drawings are included to provide a further understanding of inventive concepts, and are incorporated in and constitute a part of this specification. The drawings illustrate embodiments of inventive concepts and, together with the description, serve to explain principles of inventive concepts. In the drawings:

FIG. 1 is a plan view illustrating a semiconductor device according to some embodiments of inventive concepts;

FIG. 2 is a cross-sectional view taken along line A-A′ of FIG. 1;

FIG. 3A is a cross-sectional view taken along line A-A′ of FIG. 1;

FIG. 3B is a cross-sectional view taken along line A-A′ of FIG. 1;

FIG. 4 is a cross-sectional view taken along line A-A′ of FIG. 1;

FIG. 5 is a plan view illustrating a semiconductor device according to some embodiments of inventive concepts;

FIG. 6 is a cross-sectional view taken along line A-A′ of FIG. 5;

FIG. 7 is a cross-sectional view taken along line A-A′ of FIG. 5;

FIG. 8 is a plan view illustrating a semiconductor device according to some embodiments of inventive concepts;

FIG. 9 is a cross-sectional view taken along line A-A′ of FIG. 8;

FIG. 10 is a cross-sectional view taken along line A-A′ of FIG. 8;

FIG. 11 is a plan view illustrating a semiconductor device according to some embodiments of inventive concepts;

FIG. 12 is a cross-sectional view taken along line A-A′ of FIG. 11;

FIG. 13 is a plan view illustrating a semiconductor device according to some embodiments of inventive concepts;

FIG. 14 is a cross-sectional view taken along line A-A′ of FIG. 13;

FIG. 15 is a plan view illustrating a semiconductor device according to some embodiments of inventive concepts;

FIG. 16 is a cross-sectional view taken along line A-A′ of FIG. 15;

FIG. 17 is a plan view illustrating a semiconductor device according to some embodiments of inventive concepts;

FIGS. 18 to 21 are diagrams illustrating a method for manufacturing a semiconductor device according to some embodiments of inventive concepts;

FIG. 22 is a diagram illustrating a method for manufacturing a semiconductor device according to some embodiments of inventive concepts;

FIG. 23 is a diagram illustrating a method for manufacturing a semiconductor device according to some embodiments of inventive concepts; and

FIG. 24 is a diagram illustrating a method for manufacturing a semiconductor device according to some embodiments of inventive concepts.

### DETAILED DESCRIPTION

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

The notion that elements are “substantially the same” may indicate that the element may be completely the same and may also indicate that the elements may be determined to be the same in consideration of errors or deviations occurring during a process.

Hereinafter, embodiments of inventive concepts will be described with reference to the accompanying drawings in more detail in order to more specifically describe inventive concepts.

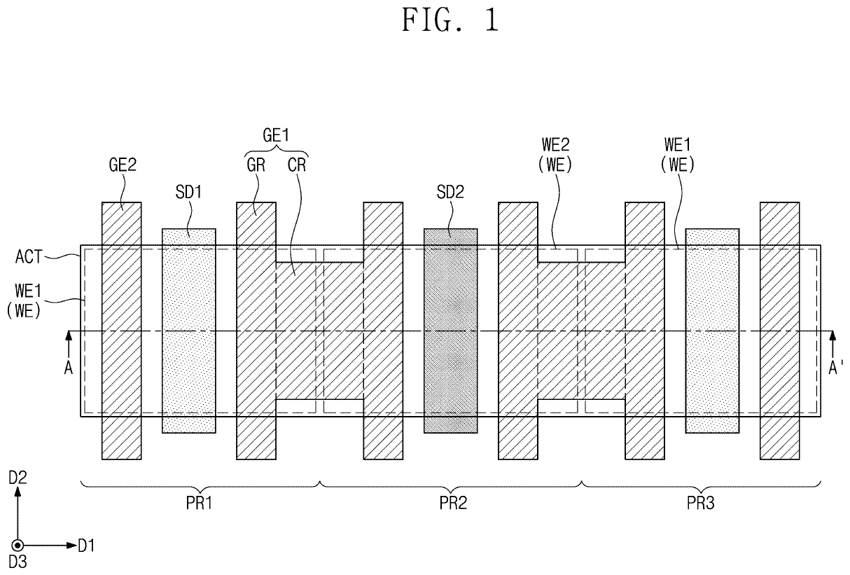

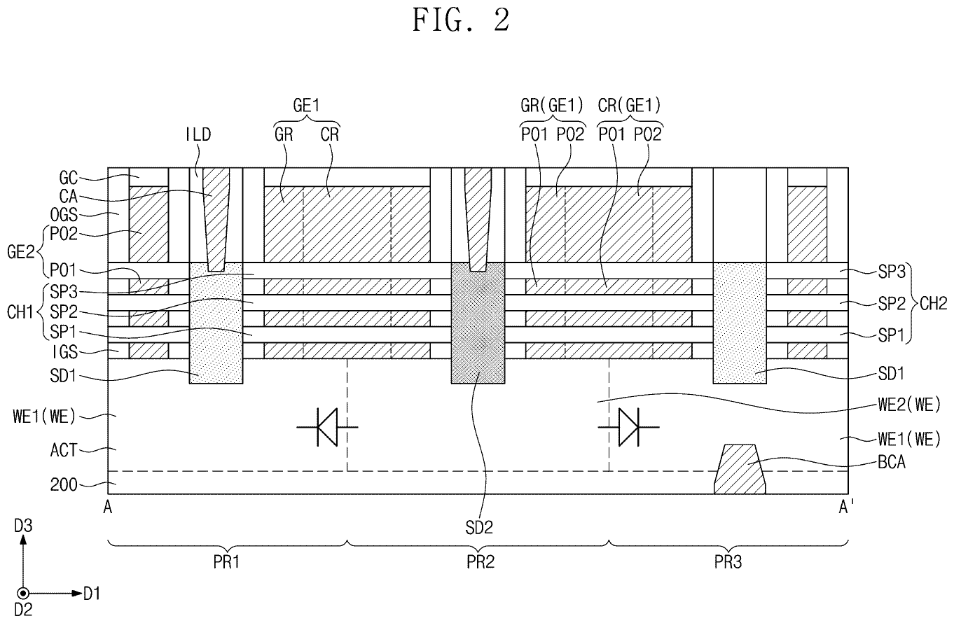

FIG. 1 is a plan view illustrating a semiconductor device according to some embodiments of inventive concepts. FIG. 2 is a cross-sectional view taken along line A-A′ of FIG. 1.

Referring to FIGS. 1 and 2, a substrate 100 including a first region PR1, a second region PR2 and a third region PR3 may be provided. For example, the substrate 100 may be a semiconductor substrate or compound semiconductor substrate including at least one of silicon, germanium, or silicon-germanium. In the present disclosure, each of the wordings, “A or B”, “at least one of A and B”, “at least one of A or B”, “A, B or C”, “at least one of A, B and C” and “at least one of A, B or C” may include any one or all possible combinations among items listed together with the corresponding phrase therein. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC. For example, the substrate 100 may have a shape of a plate extending along a first direction D1 and a second direction D2. The first direction D1 and the second direction D2 may be parallel to an upper surface of the substrate 100 and may cross each other. The first to third regions PR1, PR2 and PR3 may be adjacent to each other in the first direction D1.

An active pattern ACT may be defined by a trench (not shown) of an upper portion of the substrate 100. The active pattern ACT may extend on the substrate 100 along the first direction D1. The active pattern ACT may be a portion of the substrate 100. For example, the portion of the substrate 100 may protrude in a third direction D3. The third direction D3 may be a direction vertical to an upper surface of the substrate 100. For convenience of description, in the present specification, as long as there is no separate description, the substrate 100 is defined as the other portion except for the portion (in other words, the active pattern ACT) of the substrate 100.

The active pattern ACT may include a well region WE. The well region WE may include at least one of an N-type conductive impurity or a P-type conductive impurity. The well region WE may include a first well region WE1 on each of the first region PR1 and the third region PR3 and a second well region WE2 on the second region PR2. For example, the first well region WE1 may include the N-type conductive impurity, and the second well region WE2 may include the P-type conductive impurity. Accordingly, a P-N junction may be formed between the first well region WE1 on the first region PR1 and the second well region WE2 on the second region PR2. In the same manner, a P-N junction may be formed between the second well region WE2 on the second region PR2 and the first well region WE1 on the third region PR3.

An element isolation pattern (not shown) including an insulating material may be provided on the substrate 100, and may fill the trench.

Each of a first semiconductor pattern CH1 and a second semiconductor pattern CH2 may be provided on the active pattern ACT. Each of a first semiconductor pattern CH1 and a second semiconductor pattern CH2 may be provided in plurality. The first semiconductor patterns CH1 may be disposed spaced apart from each other along the first direction D1. The second semiconductor patterns CH2 may be disposed spaced apart from each other along the first direction D1.

Each of the first semiconductor pattern CH1 and the second semiconductor pattern CH2 may include a first semiconductor layer SP1, a second semiconductor layer SP2 and a third semiconductor layer SP3 adjacent to each other in the third direction D3, but embodiments of inventive concepts are not limited thereto. For example, the first semiconductor pattern CH1 may include at least four semiconductor layers. Each of the first to third semiconductor layers SP1, SP2, and SP3 may include crystalline silicon. With respect to the first direction D1, at the same vertical level, the first semiconductor pattern CH1 may have a greater width than the second semiconductor pattern CH2.

A first recess RS1 may be defined between the first semiconductor pattern CH1 and the second semiconductor pattern CH2. A second recess RS2 may be defined between the first semiconductor patterns CH1.

A first impurity pattern SD1 and a second impurity pattern SD2 may be provided on the active pattern ACT. The first impurity pattern SD1 may fill the first recess RS1, and the second impurity pattern SD2 may fill the second recess RS2. Each of the first and second impurity patterns SD1 and SD2 may be connected to the first to third semiconductor layers SP1, SP2, and SP3. The first impurity pattern SD1 and the second impurity pattern SD2 may be disposed spaced apart from each other in the first direction D1.

The first impurity pattern SD1 and the second impurity pattern SD2 may include different materials. For example, the first impurity pattern SD1 may include the same semiconductor element (for example, Si) as the first semiconductor pattern CH1. For example, the second impurity pattern SD2 may include a semiconductor element (for example, SiGe) having a greater lattice parameter than a semiconductor element of the first semiconductor pattern CH1.

The first impurity pattern SD1 and the second impurity pattern SD2 may include different conductive impurities. For example, the first impurity pattern SD1 may include an N-type conductive impurity, and the second impurity pattern SD2 may include a P-type conductive impurity.

Although not shown, the first impurity patterns SD1 may be disposed spaced apart from each other with the second semiconductor pattern CH2 therebetween. In other words, the first and second impurity patterns SD1 and SD2 disposed spaced apart from each other with the first semiconductor pattern CH1 therebetween may include different conductive impurities. In addition, the first impurity patterns SD1 disposed spaced apart from each other with the second semiconductor pattern CH2 therebetween may include the same conductive impurity.

The first region PR1 may constitute one logic cell with the second region PR2 and the third region PR3. In the present disclosure, the logic cell may mean a logic element (for example, AND, OR, XOR, XNOR, an inverter, or the like) that performs a specific function. In the present specification, the logic cell constituted by the first to third regions PR1, PR2, and PR3 is referred to as a first logic cell. The first logic cell may include diodes for constituting the logic element and lines connecting the diodes each other. Specifically, the first impurity pattern SD1, the second impurity pattern SD2, the first well region WE1 and the second well region WE2 may constitute a diode, and active contacts CA to be described later may partially constitute the lines.

One first logic cell is illustrated in the drawing, but embodiments of inventive concepts are not limited thereto. For example, a second logic cell including a logic element that performs a different function from the first logic cell may be disposed adjacent to the first logic cell. The second logic cell may include transistors for constituting a logic element and lines connecting the transistors each other. Two logic cells are described above, but embodiments of inventive concepts are not limited thereto, and functions, a number, and disposition of the logic cells may be variously changed by those skilled in the art.

A first gate pattern GE1 may be provided on the first semiconductor pattern CH1, and may cross the first semiconductor pattern CH1. A second gate pattern GE2 may be provided on the second semiconductor pattern CH2, and may cross the second semiconductor pattern CH2. The first gate pattern GE1 and the second gate pattern GE2 may be spaced apart from each other in the first direction D1, and may each extend along the second direction D2. Each of the first gate pattern GE1 and the second gate pattern GE2 may be provided in plurality. The first gate patterns GE1 may be spaced apart from each other in the first direction D1, and the second gate patterns GE2 may be spaced apart from each other in the first direction D1.

The first gate pattern GE1 may include a gate region GR extending along the second direction D2, and an extension region CR extending from the gate region GR along the first direction D1. The gate region GR may include gate regions GR adjacent to each other in the first direction D1. The extension region CR may be interposed between the gate regions GR, and may connect the gate regions GR. Accordingly, on a plan view, the first gate pattern GE1 may have an H shape. The extension region CR may have an integrated shape with the gate regions GR. For example, with respect to the first direction D1, at the same vertical level, the extension region CR may substantially have the same width as or a greater width than the gate region GR. For example, with respect to the second direction D2, at the same vertical level, the extension region CR may have a smaller width than the gate region GR.

One of the gate regions GR may be more adjacent to the first impurity pattern SD1 than the extension region CR. The other one of the gate regions GR may be more adjacent to the second impurity pattern SD2 than the extension region CR. The gate regions GR and the extension region CR may be interposed between the first impurity pattern SD1 and the second impurity pattern SD2.

The extension region CR may be provided on the P-N junction. That is, the extension region CR may be provided on a boundary on which the first well region WE1 and the second well region WE2 meet each other. A portion of the extension region CR may be provided on the first well region WE1, and the other portion of the extension region CR may be provided on the second well region WE2. The extension region CR may be provided on the boundary on which the first well region WE1 and the second well region WE2 meet each other, to form a greater width of the first semiconductor pattern CH1 along the first direction D1. Accordingly, a distance between the first impurity pattern SD1 and the second impurity pattern SD2 may become greater. As a result, leakage current between the first impurity pattern SD1 and the second impurity pattern SD2 through the first semiconductor pattern CH1 may be reduced. Accordingly, electrical characteristics of a semiconductor device may be improved.

The extension region CR may be provided on the first semiconductor pattern CH1, and may vertically overlap the first semiconductor pattern CH1. With respect to the second direction D2, the extension region CR may substantially have the same width as or a smaller width than the first semiconductor pattern CH1. With respect to the second direction D2, the gate region GR may have a greater width than the first semiconductor pattern CH1.

With respect to the first direction D1, at the same vertical level, the first gate pattern GE1 may have a greater width than the second gate pattern GE2. For example, with respect to the first direction D1, at the same vertical level, the extension region CR may substantially have the same width as or a greater width than the second gate pattern GE2. With respect to the second direction D2, at the same vertical level, the extension region CR may have a smaller width than the second gate pattern GE2.

The gate region GR and the extension region CR of the first gate pattern GE1, and the second gate pattern GE2 may each include an inner portion PO1 and an outer portion P02. The inner portion PO1 may be interposed between an uppermost semiconductor layer SP3 among a plurality of semiconductor layers SP1, SP2 and SP3, and the active pattern ACT. The outer portion P02 may be provided on the uppermost semiconductor layer. For example, the inner portion PO1 may include three inner portions, but embodiments of inventive concepts are not limited thereto. For example, the inner portion PO1 may include at least four inner portions.

Each of the first gate pattern GE1 and the second gate pattern GE2 may include a first metal pattern, and a second metal pattern on the first metal pattern. For example, the first metal pattern may include at least one of a metal material (for example, Ti, Mo, W, Cu, Al, Ta, Ru, Ir, Co, or the like), or a metal nitride (for example, a nitride of Ti, Mo, W, Cu, Al, Ta, Ru, Ir, Co, or the like). For example, the first metal pattern may further include carbon (C). For example, the first metal pattern may include metal materials having different work-functions from each other.

For example, the second metal pattern may include a metal material (for example, Ti, Mo, W, Cu, Al, Ta, Ru, Ir, Co, or the like) having a lower resistance than the first metal pattern.

For example, the inner portion PO1 may include the first metal pattern. For example, the outer portion P02 may include the first metal pattern, and the second metal pattern.

For example, in the case of the first logic cell utilized as a diode through a P-N junction between the first well region WE1 and the second well region WE2, channel formation of the first semiconductor pattern CH1 may be controlled by controlling a voltage applied to the first gate pattern GE1. Accordingly, the leakage current between the first impurity pattern SD1 and the second impurity pattern SD2 through the first semiconductor pattern CH1 may be controlled.

A gate capping pattern GC may be provided on an upper surface of each of the first gate pattern GE1 and the second gate pattern GE2. For example, the gate capping pattern GC may include at least one of SiON, SiCN, SiOCN, or SiN.

External gate spacers OGS may be provided on side surfaces of the outer portion P02 of each of the first gate pattern GE1 and the second gate pattern GE2, and may extend onto each of side surfaces of the gate capping pattern GC.

Internal gate spacers IGS may be interposed between the first impurity pattern SD1 and the inner portion PO1 of the first gate pattern GE1, between the first impurity pattern SD1 and the inner portion PO1 of the second gate pattern GE2, and between the second impurity pattern SD2 and the inner portion PO1 of the first gate pattern GE1. For example, each of the external gate spacer OGS and the internal gate spacer IGS may include an insulating material.

A gate insulating pattern (not shown) may be interposed between the first gate pattern GE1 and the first to third semiconductor layers SP1, SP2, and SP3, and between the second gate pattern GE2 and the first to third semiconductor layers SP1, SP2, and SP3. For example, the gate insulating pattern may include at least one of silicon oxide (SiO2), silicon oxynitride (SiON) or a high dielectric material. In the present disclosure, the high dielectric material is defined as a material having a higher dielectric constant than silicon oxide.

An interlayer insulating layer ILD may be provided on the substrate 100. The interlayer insulating layer ILD may cover the external gate spacers OGS, the first impurity pattern SD1 and the second impurity pattern SD2. For example, the interlayer insulating layer ILD may include silicon oxide (SiO2).

The active contact CA may penetrate the interlayer insulating layer ILD. A lower portion of the active contacts CA may be buried in an upper portion of at least one of the first impurity pattern SD1 or the second impurity pattern SD2. For example, the active contacts CA may include at least one of a metal material (for example, Ti, Mo, W, Cu, Al, Ta, Ru, Ir, Co, or the like), a metal silicide (for example, a silicide of Ti, Mo, W, Cu, Al, Ta, Ru, Ir, or the like), or a metal nitride (for example, a nitride of Ti, Mo, W, Cu, Al, Ta, Ru, Ir, Co, or the like). A voltage applied to the active contact CA may be transmitted to the first well region WE1 through the first impurity pattern SD1. The voltage applied to the active contact CA may be transmitted to the second well region WE2 through the second impurity pattern SD2.

Gate contacts (not shown) may penetrate the gate capping pattern GC. Each of the gate contacts may be buried in an upper portion of the outer portion P02 of each of the first gate pattern GE1 and the second gate pattern GE2. For example, the gate contacts may include at least one of a metal material (for example, Ti, Mo, W, Cu, Al, Ta, Ru, Ir, Co, or the like), or a metal nitride (for example, a nitride of Ti, Mo, W, Cu, Al, Ta, Ru, Ir, Co, or the like).

Although not shown, separate lines including a conductive material may be provided as a plurality of layers. The lines may be connected to the active contacts CA and the gate contacts (not shown). Some of the lines may apply voltages to the first impurity pattern SD1 through the active contact CA, and the others may apply voltages to the second impurity pattern SD2 through the active contact CA. The first logic cell may be utilized as a logic element that performs a function of a diode by controlling the voltages.

A rear surface active contact BCA may penetrate the substrate 100, and the rear surface active contact BCA may be partially buried inside the first well region WE1 on the third region PR3. For example, the rear surface active contact BCA may include at least one of a metal material (for example, Ti, Mo, W, Cu, Al, Ta, Ru, Ir, Co, or the like), a metal silicide (for example, a silicide of Ti, Mo, W, Cu, Al, Ta, Ru, Ir, or the like), or a metal nitride (for example, a nitride of Ti, Mo, W, Cu, Al, Ta, Ru, Ir, Co, or the like).

A power transmission network layer (not shown) may be provided on a lower surface of the substrate 100. The power transmission network layer may include a plurality of lower lines (not shown) electrically connected to the rear surface active contact BCA. A voltage applied to the rear surface active contact BCA may be transmitted to the first well region WE1 on the third region PR3 through the power transmission network layer.

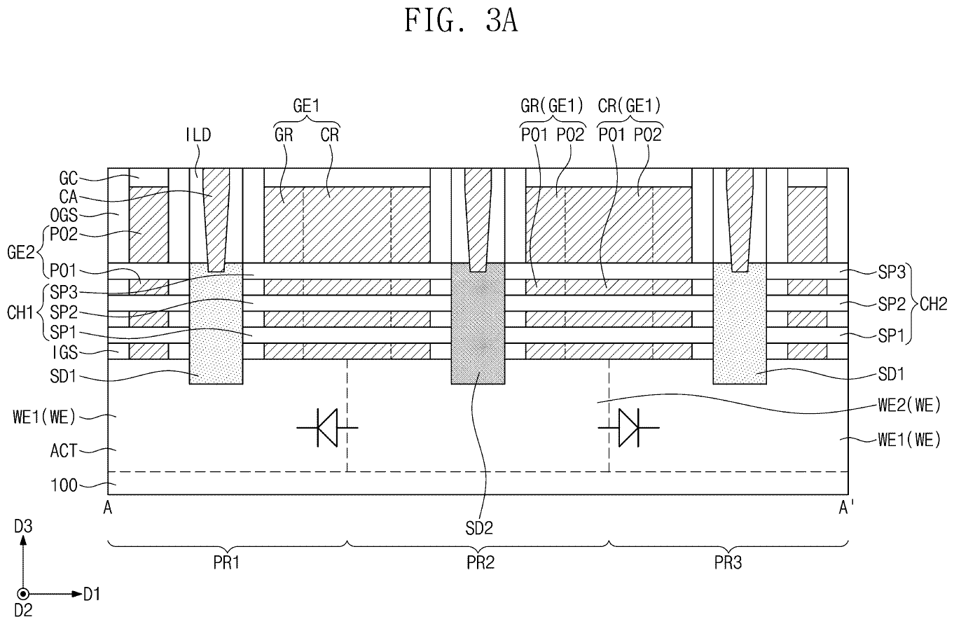

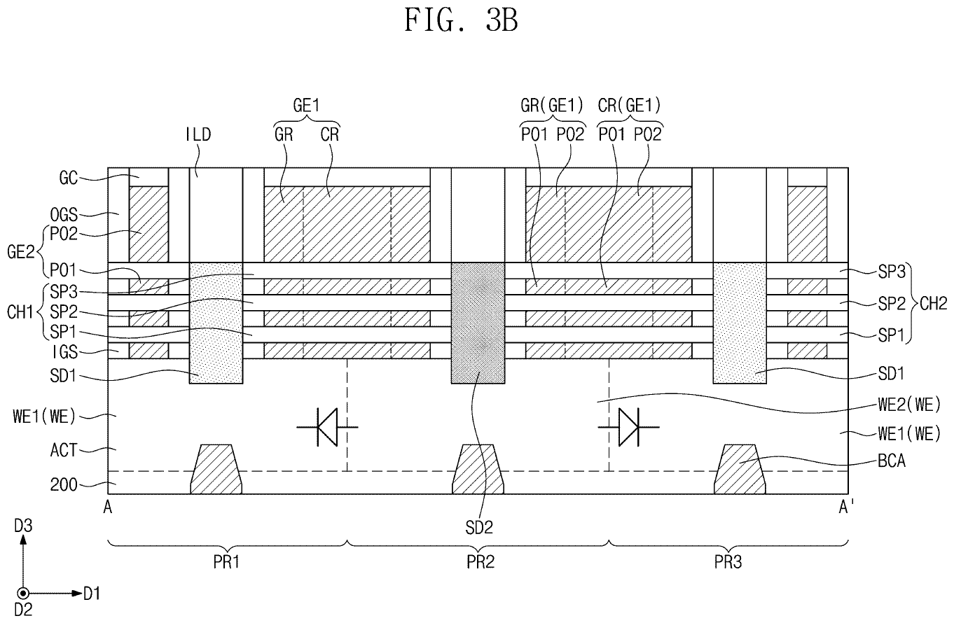

Hereinafter, a semiconductor device according to other embodiments of inventive concepts will be described with reference to FIGS. 3A to 17. For simplification of description, duplicate description of that described above will be omitted, and a difference from that described above will be mainly described.

FIG. 3A is a cross-sectional view taken along line A-A′ of FIG. 1. FIG. 3B is a cross-sectional view taken along line A-A′ of FIG. 1.

Referring to FIGS. 1, 3A and 3B, for example, in addition to what is described with reference to FIGS. 1 and 2, a method for supplying voltages to the first well region WE1 and the second well region WE2 may be variously performed.

At first, referring to FIG. 3A, the rear surface active contact BCA described with reference to FIGS. 1 and 2 may be omitted. Instead, the active contact CA may be provided on the first impurity pattern SD1 on the third region PR3. Accordingly, a voltage applied to the active contact CA and the first impurity pattern SD1 may be transmitted to the first well region WE1 on the third region PR3 through upper lines.

Next, referring to FIG. 3B, the active contact CA described with reference to FIGS. 1 and 2 may be omitted. Instead, the rear surface active contact BCA may be provided under the first well region WE1 on the first region PR1 and under the second well region WE2 on the second region PR2. Accordingly, a voltage applied to the rear surface active contact BCA may be transmitted to the first well region WE1 on the first region PR1 and the second well region WE2 on the second region PR2 through the power transmission network layer.

Existence, location, a number and a disposition method of each of the active contact CA and the rear surface active contact BCA are not limited to what is described above, and may be variously changed by those skilled in the art.

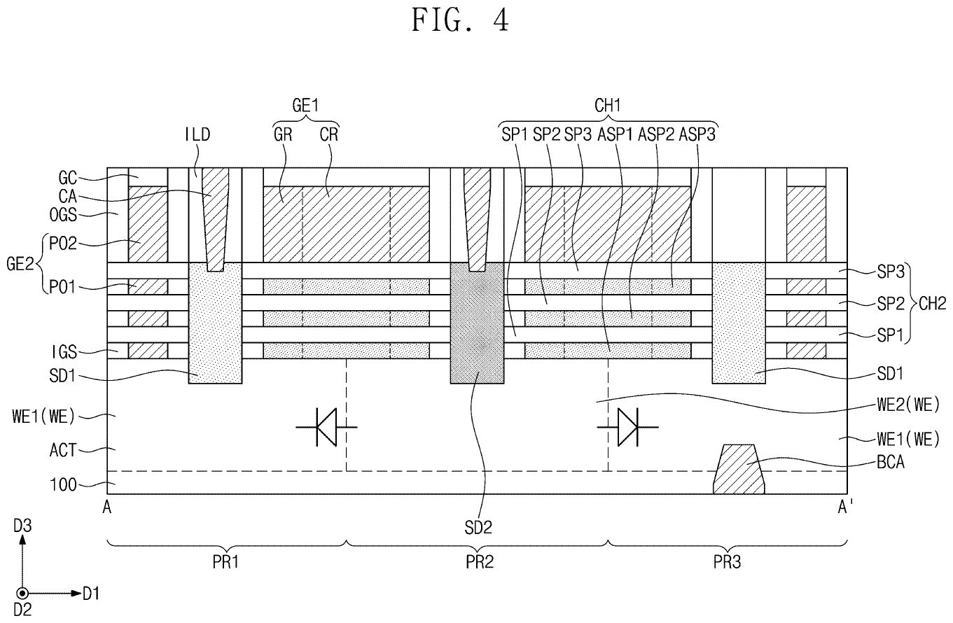

FIG. 4 is a cross-sectional view taken along line A-A′ of FIG. 1.

Referring to FIGS. 1 and 4, the inner portion PO1 of each of the gate region GR and the extension region CR of the first gate pattern GE1 described with reference to FIG. 2 may not be provided. Accordingly, a first additional semiconductor layer ASP1 may be provided in a region in which the inner portion PO1 (see FIG. 2) between the active pattern ACT and the first semiconductor layer SP1 is provided. A second additional semiconductor layer ASP2 may be provided in a region in which the inner portion PO1 (see FIG. 2) between the first semiconductor layer SP1 and the second semiconductor layer SP2 is provided. A third additional semiconductor layer ASP3 may be provided in a region in which the inner portion PO1 (see FIG. 2) between the second semiconductor layer SP2 and the third semiconductor layer SP3 is provided.

The first to third additional semiconductor layers ASP1, ASP2 and ASP3 may constitute the first semiconductor pattern CH1 together with the first to third semiconductor layers SP1, SP2, and SP3. For example, each of the first to third additional semiconductor layers ASP1, ASP2 and ASP3 may include a semiconductor element (for example, SiGe) having a greater lattice parameter than a semiconductor element of each of the first to third semiconductor layers SP1, SP2, and SP3.

The first to third additional semiconductor layers ASP1, ASP2 and ASP3 may be provided to expand an area on which current may flow between the active contact CA and the well region WE. Specifically, the current may flow through a portion of each of the first to third additional semiconductor layers ASP1, ASP2 and ASP3 adjacent to the first impurity pattern SD1 as well as the first impurity pattern SD1 interposed between the active contact CA and the first well region WE1. In the same manner, the current may flow through the other portion of each of the first to third additional semiconductor layers ASP1, ASP2 and ASP3 adjacent to the second impurity pattern SD2 as well as the second impurity pattern SD2 interposed between the active contact CA and the second well region WE2. Accordingly, electrical characteristics of the semiconductor device may be improved by expanding the area on which the current may flow between the active contact CA and the well region WE.

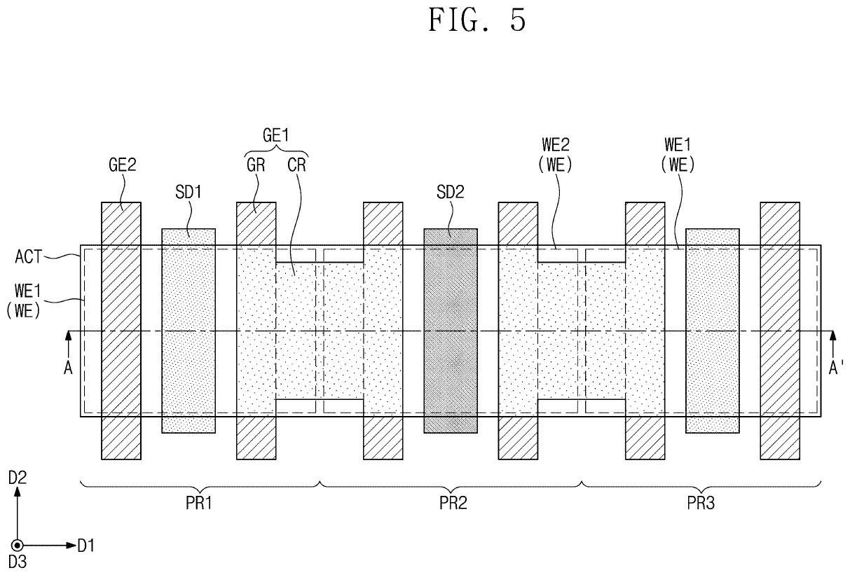

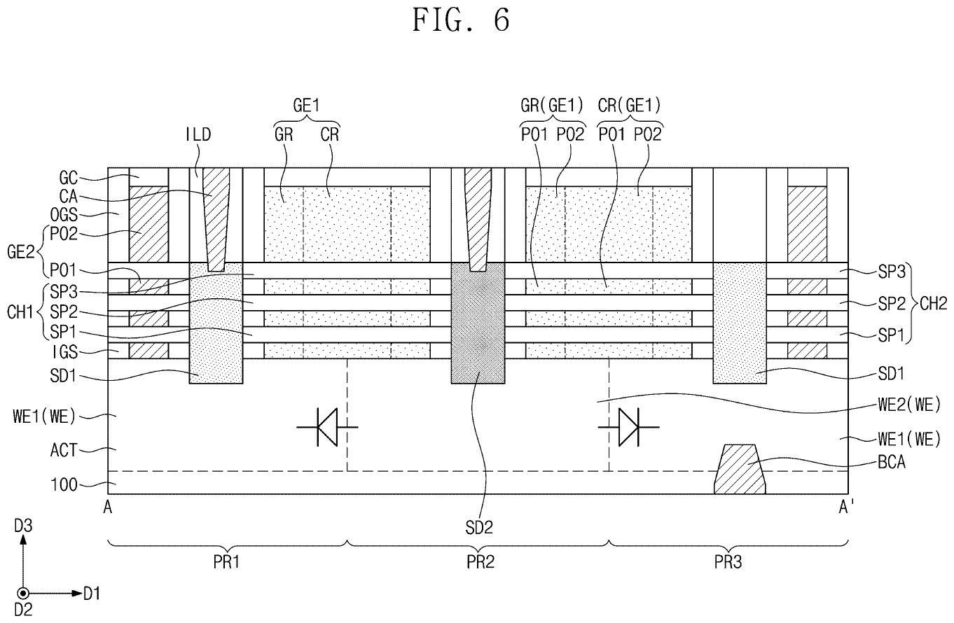

FIG. 5 is a plan view illustrating a semiconductor device according to some embodiments of inventive concepts. FIG. 6 is a cross-sectional view taken along line A-A′ of FIG. 5.

Referring to FIGS. 5 and 6, unlike what is described with reference to FIGS. 1 and 2, the inner portion PO1 and the outer portion P02 of the extension region CR may include an insulating material. A portion of each of the inner portion PO1 and the outer portion P02 of the gate region GR may include an insulating material. The portion of the outer portion P02 of the gate region GR may be adjacent to the outer portion P02 of the extension region CR in the first direction D1.

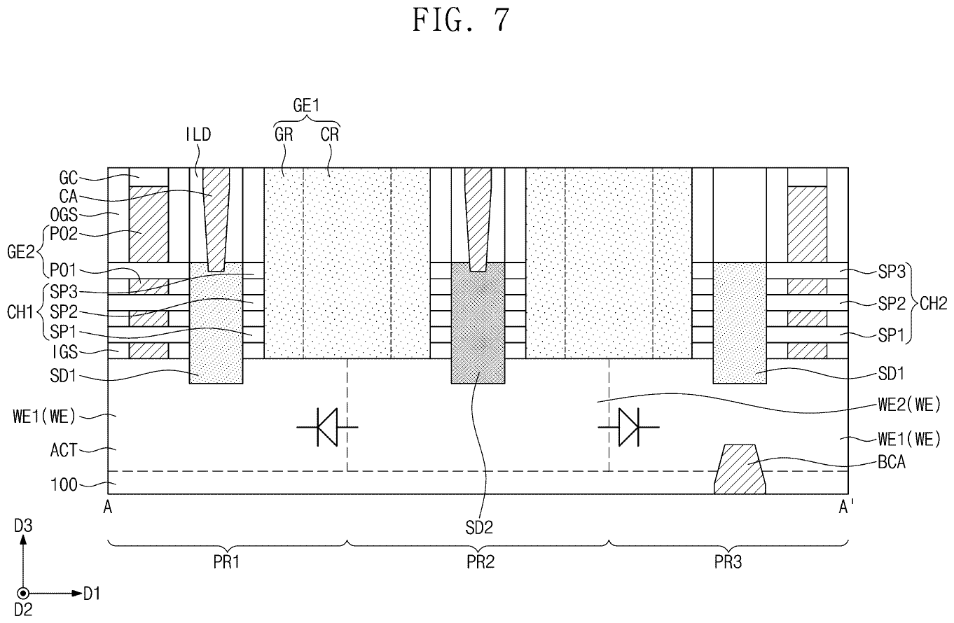

FIG. 7 is a cross-sectional view taken along line A-A′ of FIG. 5.

Referring to FIGS. 5 and 7, each of the gate region GR and the extension region CR may penetrate the first semiconductor pattern CH1. Accordingly, the first semiconductor pattern CH1 may be separated into a pair of the first semiconductor patterns CH1 between the first impurity pattern SD1 and the second impurity pattern SD2.

Unlike what is described with reference to FIG. 6, each of the gate region GR and the extension region CR may not be separated into the inner portion PO1 (see FIG. 6) and the outer portion P02 (see FIG. 6), and may extend along the third direction D3.

Unlike what is described with reference to FIGS. 1 and 2, a portion of the gate region GR and the extension region CR may include an insulating material. Accordingly, leakage current between the first impurity pattern SD1 and the second impurity pattern SD2 through the first semiconductor pattern CH1 may be blocked. Accordingly, electrical characteristics of the semiconductor device may be improved.

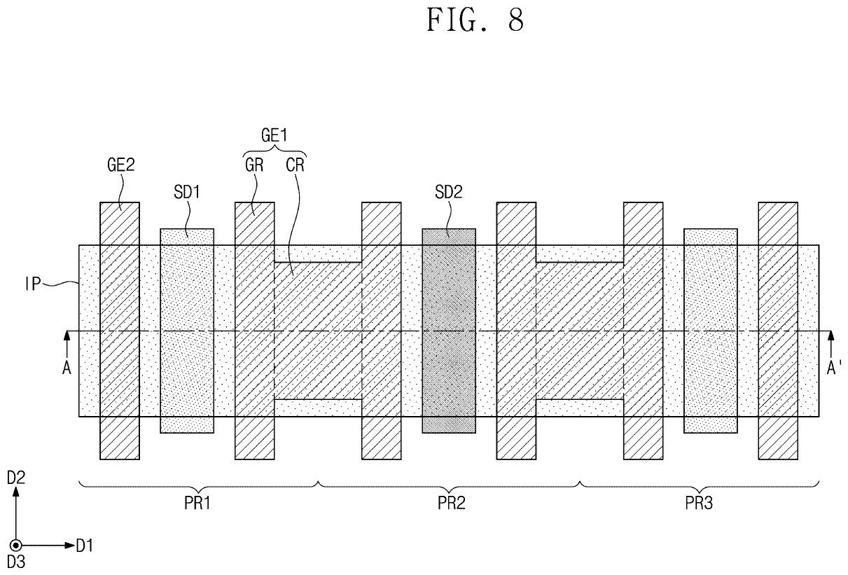

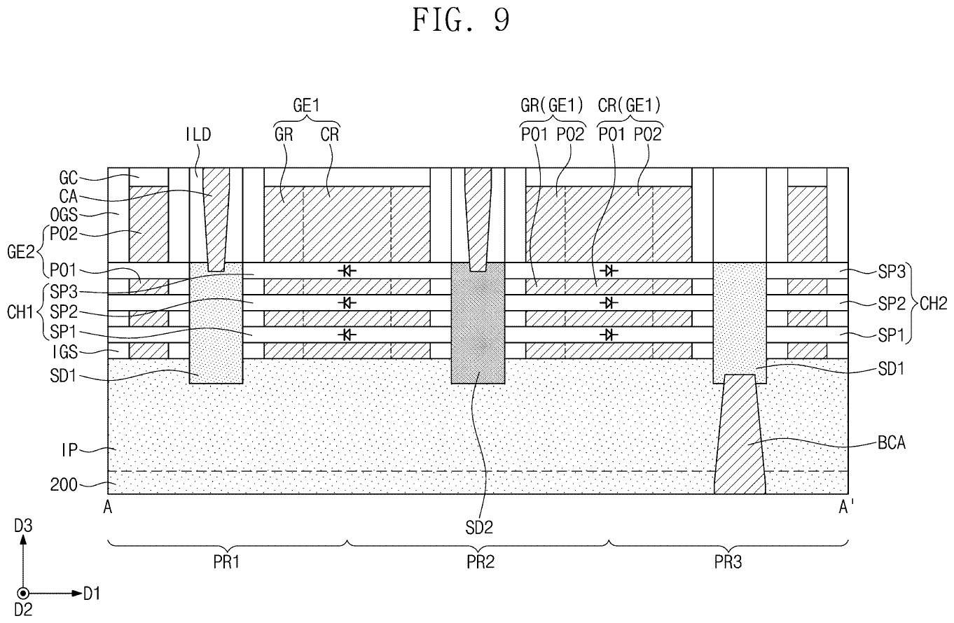

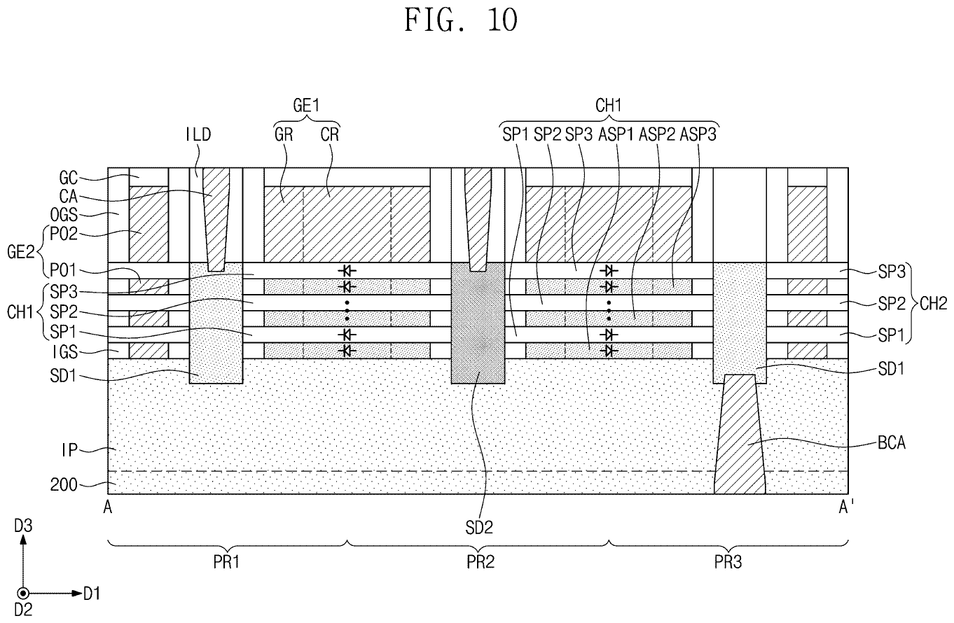

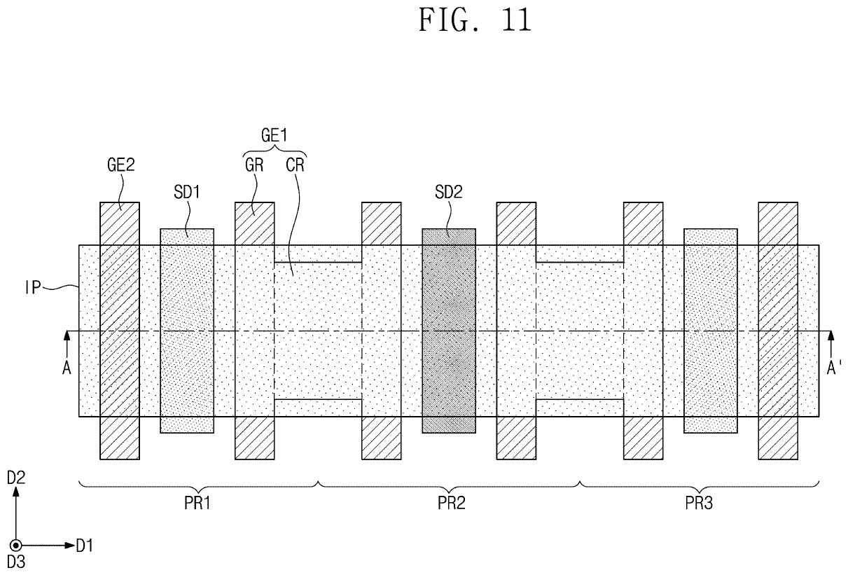

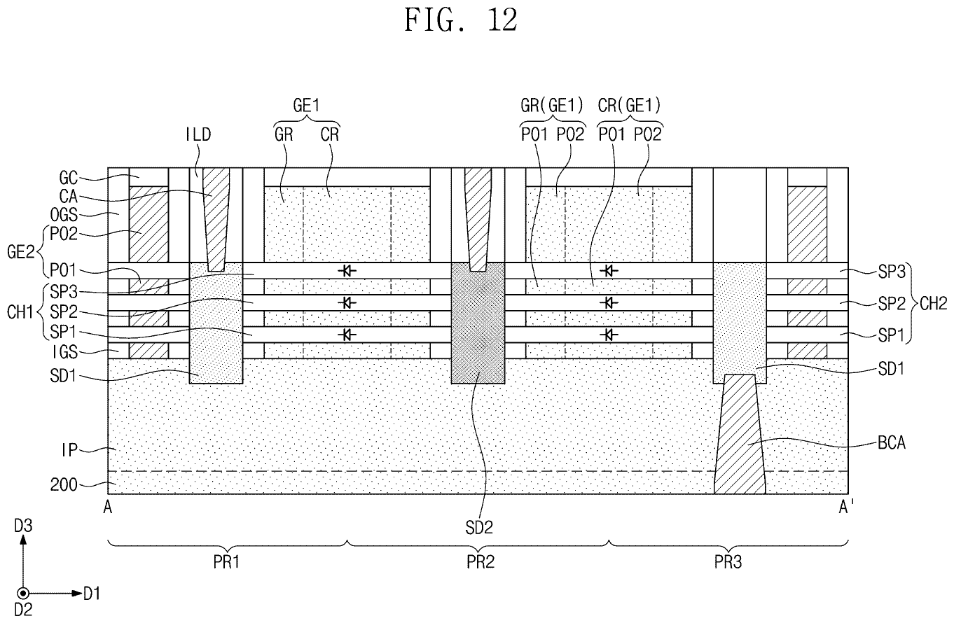

FIG. 8 is a plan view illustrating a semiconductor device according to some embodiments of inventive concepts. FIG. 9 is a cross-sectional view taken along line A-A′ of FIG. 8. FIG. 10 is a cross-sectional view taken along line A-A′ of FIG. 8. FIG. 11 is a plan view illustrating a semiconductor device according to some embodiments of inventive concepts. FIG. 12 is a cross-sectional view taken along line A-A′ of FIG. 11.

Referring to FIGS. 8 to 12, the substrate 100 and the active pattern ACT described with reference to FIGS. 1 and 2 may be omitted. Instead, an insulating substrate 200 and an insulating pattern IP on the insulating substrate 200 may be provided. Features of the insulating substrate 200 may be the same as or similar to what is described with reference to FIG. 3. The insulating pattern IP may include an insulating material. The insulating pattern IP may extend along the first direction D1. The well region WE (see FIG. 2) may not be formed in the insulating pattern IP. Accordingly, a P-N junction may not be formed in the insulating pattern IP (in other words, under the first and second impurity patterns SD1 and SD2).

The rear surface active contact BCA may penetrate each of the insulating substrate 200 and the insulating pattern IP. An upper portion of the rear surface active contact BCA may be buried in a lower portion of the first impurity pattern SD1.

For example, when each of a first logic cell and a second logic cell adjacent to the first logic cell are supplied with power through a rear surface of the insulating substrate 200, as described above, the insulating substrate 200 and the insulating pattern IP may be provided instead of the substrate 100 (see FIG. 2) and the active pattern ACT (see FIG. 2). Accordingly, the first logic cell may not include the well region WE (see FIG. 2) including the P-N junction, and may not be utilized as a diode. Accordingly, by allowing current to flow between the first impurity pattern SD1 and the second impurity pattern SD2 through another region, the first logic cell may be utilized as a diode, and degree of freedom in disposition design of a semiconductor device may be improved. This will be described below in detail.

Referring to FIGS. 8 and 9, the first logic cell may be utilized as a diode by allowing current to flow between the first impurity pattern SD1 and the second impurity pattern SD2 through the first to third semiconductor layers SP1, SP2, and SP3 between the inner portion PO1 and the outer portion P02 of the first gate pattern GE1.

Referring to FIGS. 8 and 10, the first logic cell may be utilized as a diode by allowing current to flow between the first impurity pattern SD1 and the second impurity pattern SD2 through the first to third additional semiconductor layers ASP1, ASP2 and ASP3 and the first to third semiconductor layers SP1, SP2, and SP3 between the insulating pattern IP and the first gate pattern GEL.

Referring to FIGS. 11 and 12, the first logic cell may be utilized as a diode by allowing current to flow between the first impurity pattern SD1 and the second impurity pattern SD2 through the first to third semiconductor layers SP1, SP2, and SP3 between the inner portion PO1 and the outer portion P02 of the first gate pattern GE1 including an insulating material.

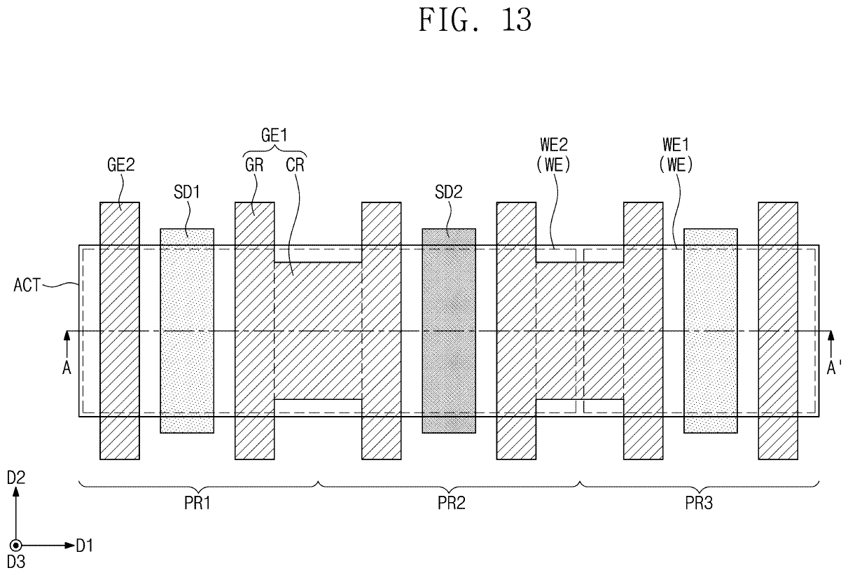

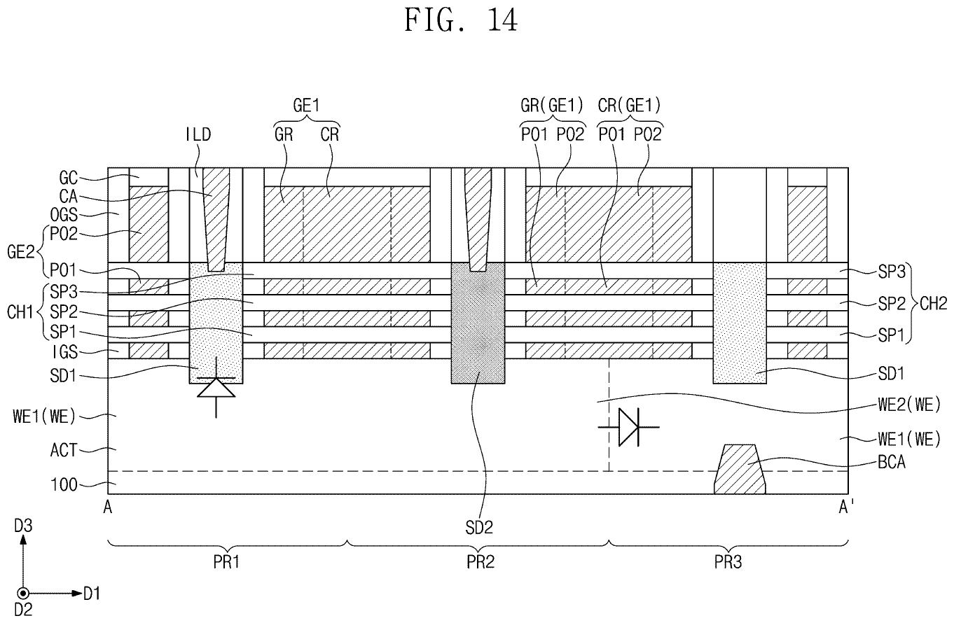

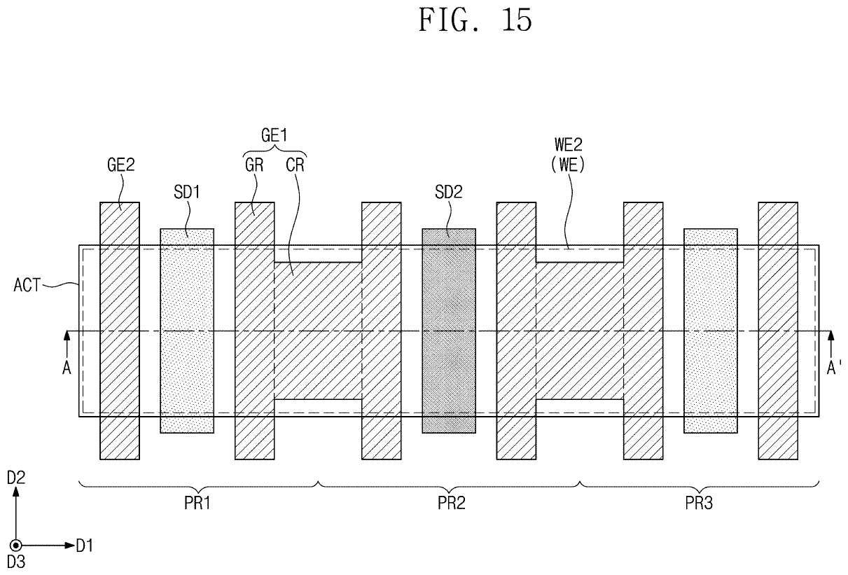

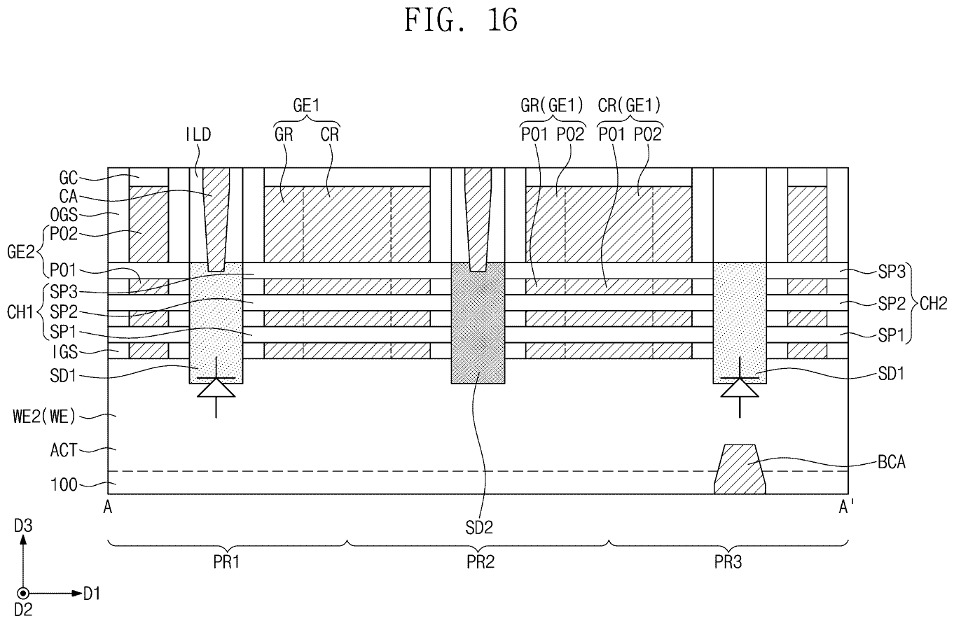

FIG. 13 is a plan view illustrating a semiconductor device according to some embodiments of inventive concepts. FIG. 14 is a cross-sectional view taken along line A-A′ of FIG. 13. FIG. 15 is a plan view illustrating a semiconductor device according to some embodiments of inventive concepts. FIG. 16 is a cross-sectional view taken along line A-A′ of FIG. 15.

Referring to FIGS. 13 to 16, unlike what is described with reference to FIGS. 1 and 2, the well region WE on the first to third regions PR1, PR2, and PR3 may be disposed in various methods.

At first, referring to FIGS. 13 and 14, the second well region WE2 may be provided on the first region PR1 and the second region PR2. The first well region WE1 may be provided on the third region PR3. Accordingly, a P-N junction may be formed between the first impurity pattern SD1 and the second well region WE2 on the first region PR1. In addition, a P-N junction may be formed between the second well region WE2 on the second region PR2 and the first well region WE1 on the third region PR3.

Next, referring to FIGS. 15 and 16, the second well region WE2 may be provided on the first to third regions PR1, PR2, and PR3. Accordingly, a P-N junction may be formed between the first impurity pattern SD1 and the second well region WE2 on the third region PR3. In addition, a P-N junction may be formed between the first impurity pattern SD1 and the second well region WE2 on the first region PR1.

Disposition of the well region WE is not limited to what is illustrated in FIGS. 13 to 16, and disposition of the well region WE on the first to third regions PR1, PR2, and PR3 may be variously changed by those skilled in the art.

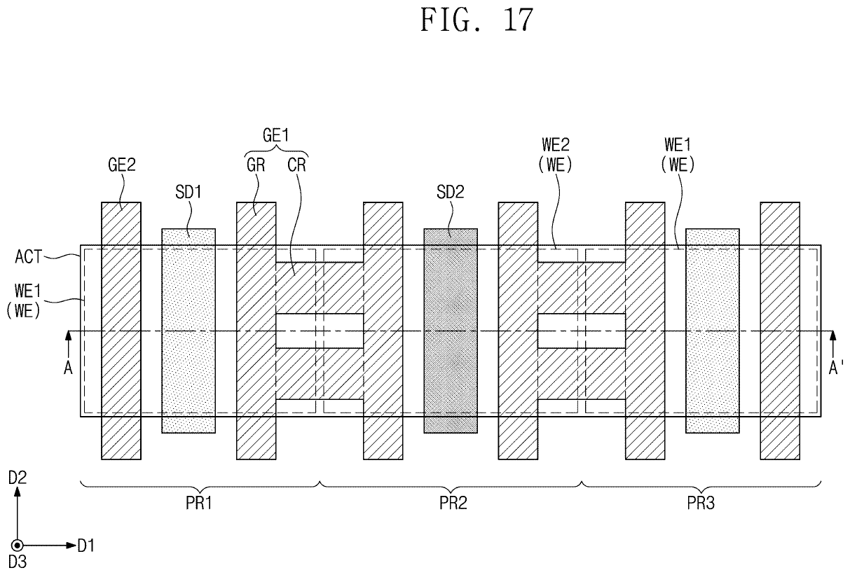

FIG. 17 is a plan view illustrating a semiconductor device according to some embodiments of inventive concepts.

Referring to FIG. 17, unlike FIG. 1, the extension region CR may be provided in plurality. The extension regions CR may be disposed spaced apart from each other between the gate regions GR in the second direction D2. Two extension regions CR are illustrated in the diagram, but embodiments of inventive concepts are not limited thereto.

Although not shown, the external gate spacers OGS (see FIG. 2) described with reference to FIG. 2 may be interposed between the extension regions CR. The external gate spacers OGS (see FIG. 2) may cover an upper surface of the first semiconductor pattern CH1 (see FIG. 2).

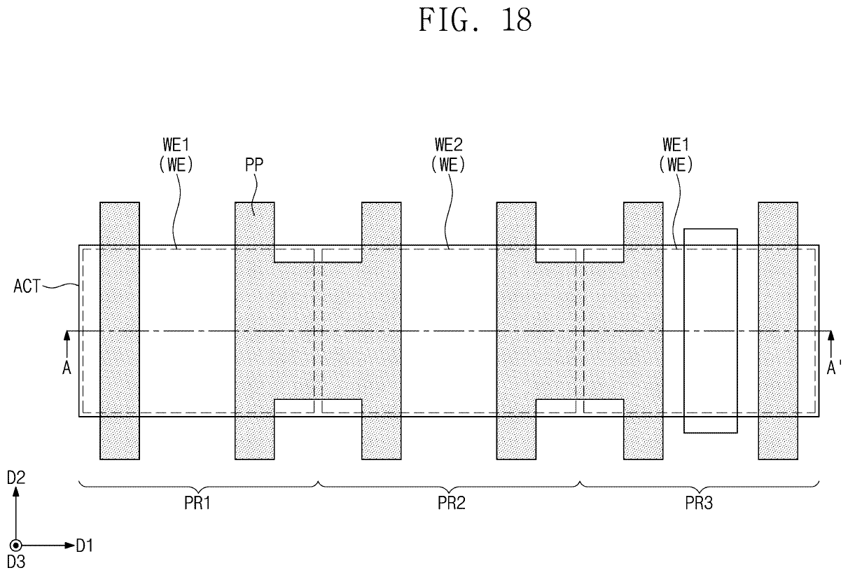

Hereinafter, a method for manufacturing a semiconductor device according to some embodiments of inventive concepts will be described with reference to FIGS. 18 to 24. For simplification of description, duplicate description of that described above will be omitted, and a difference from that described above will be mainly described.

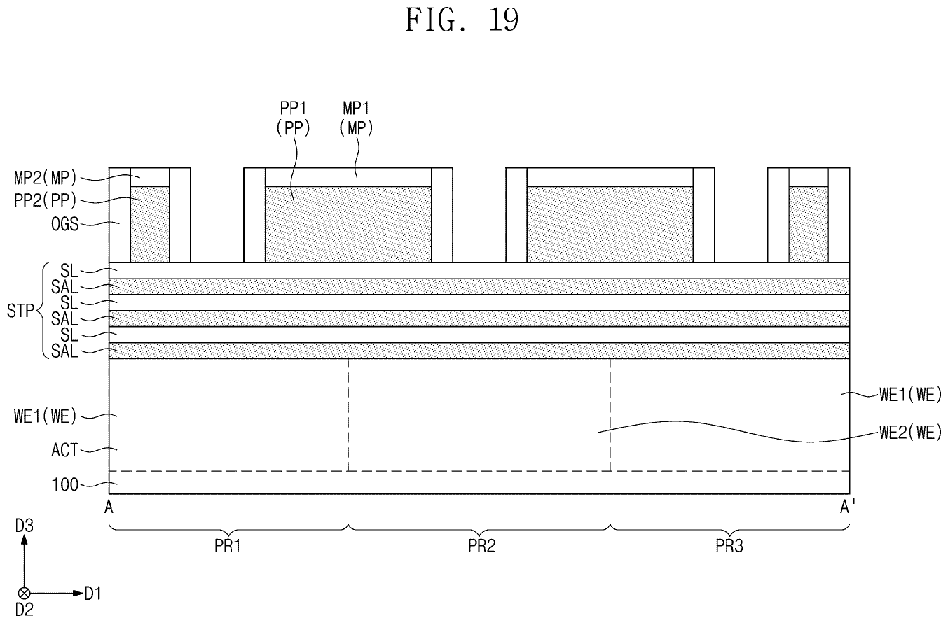

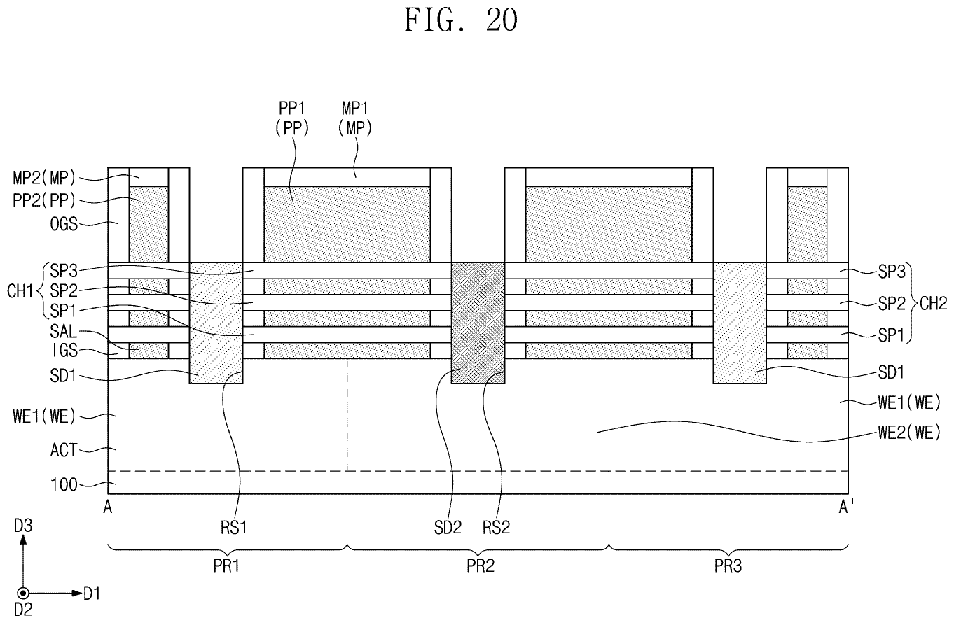

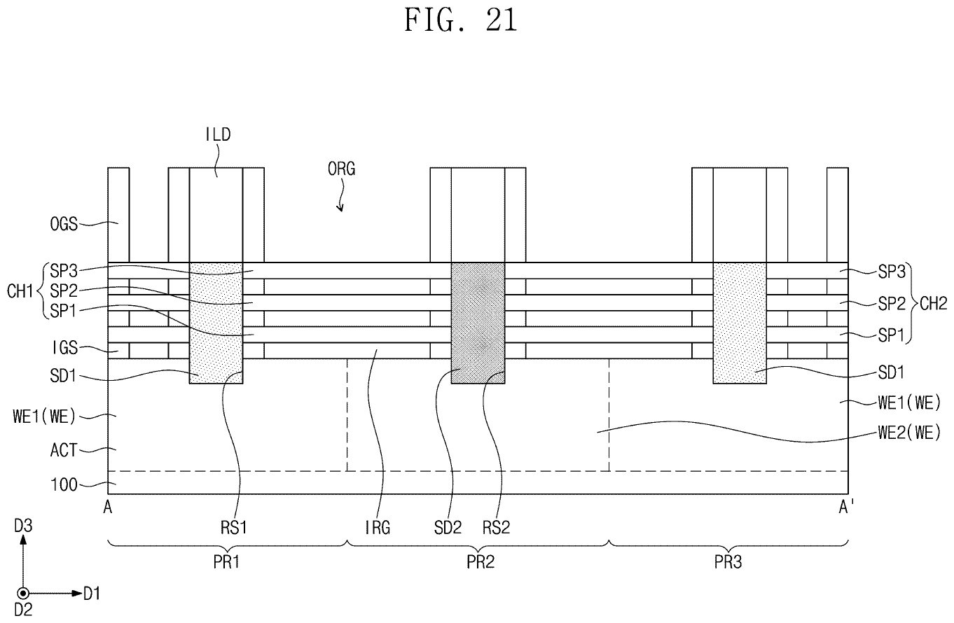

FIGS. 18 to 21 are diagrams illustrating a method for manufacturing a semiconductor device according to some embodiments of inventive concepts. Specifically, FIG. 18 is a plan view illustrating a semiconductor device according to some embodiments of inventive concepts. FIG. 19 is a cross-sectional view taken along line A-A′ of FIG. 18. FIGS. 20 and 21 are cross-sectional views each taken along line A-A′ of FIG. 1.

Referring to FIGS. 18 and 19, the substrate 100 including the active pattern ACT including each of the first well region WE1 and the second well region WE2 may be provided.

A stack pattern STP may be formed on the active pattern ACT. For example, forming the stack pattern STP may include alternately stacking semiconductor layers SL and sacrificial layers SAL on the substrate 100, forming mask patterns (not shown) extending in the first direction D1 and performing a patterning process by using the mask patterns as etching masks. When the patterning process is performed, the substrate 100 may be partially removed together, and trenches (not shown) may be formed. Element isolation patterns (not shown) may be formed to fill the trenches (not shown).

The sacrificial layers SAL may include a material capable of having etching selectivity for the semiconductor layers SL. Accordingly, when a process, of removing the sacrificial layers SAL, to be described later is performed, the sacrificial layers SAL may be removed, but the semiconductor layers SL may not be removed or may be removed less than the sacrificial layers SAL. For example, the semiconductor layers SL may include one of silicon (Si), germanium (Ge), and silicon-germanium (SiGe), and the sacrificial layers SAL may include another one, of silicon (Si), germanium (Ge), and silicon-germanium (SiGe), different from the semiconductor layers SL.

Sacrificial patterns PP may be formed to extend on the substrate 100 along the second direction D2. The sacrificial patterns PP may be formed to cover upper surfaces of the element isolation patterns, and side surfaces and an upper surface of the stack pattern. For example, forming the sacrificial patterns PP may include forming a sacrificial film (not shown) on a front side of the substrate 100, forming hard mask patterns MP on the sacrificial film, and forming the sacrificial patterns PP by partially removing the sacrificial film by using the hard mask patterns MP as etching masks. For example, the sacrificial pattern PP may include polysilicon. Thereafter, the external gate spacers OGS may be formed on side surfaces of the sacrificial patterns PP.

The sacrificial pattern PP may include a first sacrificial pattern PP1 formed on a boundary between the first well region WE1 and the second well region WE2, and a second sacrificial pattern PP2 adjacent to the first sacrificial pattern PP1 in the first direction D1. The hard mask pattern MP may include a first hard mask pattern MP1 on the first sacrificial pattern PP1 and a second hard mask pattern MP2 on the second sacrificial pattern PP2. Each of the first sacrificial pattern PP1 and the first hard mask pattern MP1 may be formed to cover an upper surface of the stack pattern STP provided on the boundary between the first well region WE1 and the second well region WE2.

The first sacrificial pattern PP1 may include some regions extending along the second direction D2, and another region extending between some regions along the first direction D1. Accordingly, on a plan view, the first sacrificial pattern PP1 may have an H shape. With respect to the first direction D1, the first sacrificial pattern PP1 may have a greater width than the second sacrificial pattern PP2.

Referring to FIGS. 1 and 20, the first recess RS1 and the second recess RS2 may be formed by partially removing the stack pattern STP by using the hard mask pattern MP and the sacrificial pattern PP as masks. The semiconductor layers SL may be separated into the first semiconductor patterns CH1 and the second semiconductor patterns CH2 spaced apart from each other in the first direction D1 by the first recess RS1 and the second recess RS2.

The sacrificial layer SAL exposed by the first recess RS1 and the second recess RS2 may be partially replaced with an insulating material. Accordingly, the internal gate spacers IGS may be formed on both side surfaces of the sacrificial layer SAL.

Thereafter, the first impurity pattern SD1 may be formed on the first recess RS1, and the second impurity pattern SD2 may be formed on the second recess RS2.

According to inventive concepts, when a process, of removing the stack pattern STP, for forming the first and second recesses RS1 and RS2 is performed, the stack pattern STP covered by an extension region, of the first sacrificial pattern PP1, extending along the first direction D1 may not be removed. Accordingly, another separate recess may not be formed on the boundary between the first well region WE1 and the second well region WE2. As a result, during a process of forming the first and second impurity patterns SD1 and SD2, another separate impurity pattern may not be unnecessarily formed on the boundary between the first well region WE1 and the second well region WE2. Accordingly, functional degradation of the first logic cell caused by an impurity pattern unnecessarily formed may be limited and/or prevented, and electrical characteristics of a semiconductor device may be improved.

Referring to FIGS. 1 and 21, the interlayer insulating layer ILD may be formed to cover the first impurity pattern SD1, the second impurity pattern SD2, the hard mask patterns MP and the external gate spacers OGS. Thereafter, the interlayer insulating layer ILD on upper surfaces of the sacrificial patterns PP may be removed. During the removing process, the hard mask patterns MP may be removed together, and the sacrificial patterns PP may be exposed.

Thereafter, the exposed sacrificial patterns PP may be removed, and an outer region ORG may be formed in a region in which the sacrificial patterns PP are removed. The first semiconductor patterns CH1, the second semiconductor patterns CH2 and the sacrificial layers SAL may be exposed to the outside by the outer region ORG.

Thereafter, the exposed sacrificial layers SAL may be selectively removed. In this case, the first to third semiconductor layers SP1, SP2, and SP3 may not be removed or may be removed less due to high etching selectivity for the sacrificial layers SAL.

Inner regions IRG may be formed in a region in which the sacrificial layers SAL are removed. Specifically, the inner regions IRG may be formed between the first to third semiconductor layers SP1, SP2, and SP3.

Referring back to FIGS. 1 and 2, a gate insulating pattern (not shown) may be formed in the outer region ORG and each of the inner regions IRG. The first gate pattern GE1 and the second gate pattern GE2 may be formed so as to fill the inner region IRG and the outer region ORG. Thereafter, the gate capping pattern GC may be formed on the outer portion P02 of each of the first gate pattern GE1 and the second gate pattern GE2.

The active contact CA may be formed so as to penetrate the interlayer insulating layer ILD, and may be connected to the first impurity pattern SD1 and the second impurity pattern SD2. A gate contact (not shown) may be formed so as to penetrate the gate capping pattern GC, and may be connected to the first gate pattern GE1 and the second gate pattern GE2.

Although not shown, separate lines including a conductive material may be formed on the interlayer insulating layer ILD, and the semiconductor device described with reference to FIGS. 1 and 3A may be manufactured.

After BEOL processes are completed, a process of turning the substrate 100 upside down may be performed. After turning the substrate 100 upside down, the rear surface active contact BCA penetrating the substrate 100 may be formed. Accordingly, the semiconductor devices described with reference to FIGS. 1, 2, and 3B may be manufactured.

After turning the substrate 100 upside down, the insulating substrate 200 (see FIG. 9) and the insulating pattern IP (see FIG. 9) may be formed in a region in which the substrate 100 and the active pattern ACT are all removed. In this case, the semiconductor device described with reference to FIGS. 8 and 9 may be manufactured.

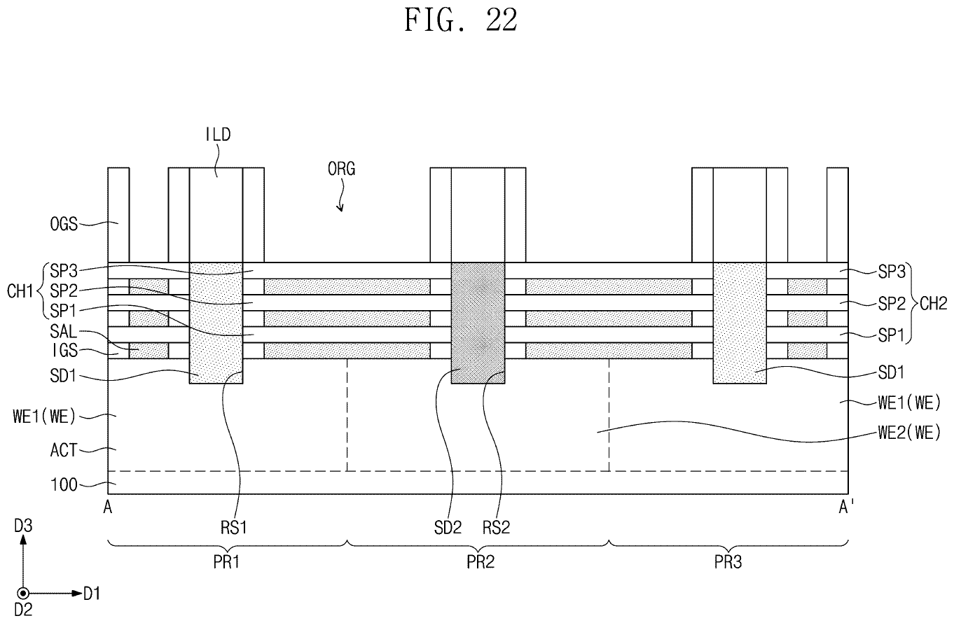

FIG. 22 is a diagram illustrating a method for manufacturing a semiconductor device according to some embodiments of inventive concepts. Specifically, FIG. 22 is a cross-sectional view taken along line A-A′ of FIG. 1.

Referring to FIGS. 1 and 22, after forming the outer region ORG described with reference to FIGS. 1 and 21, the sacrificial layers SAL may not be removed and may be left. The sacrificial layers SAL may constitute the first to third additional semiconductor layers ASP1, ASP2 and ASP3 described with reference to FIG. 4.

Thereafter, the semiconductor device described with reference to FIGS. 1 and 4 may be manufactured using the method for manufacturing a semiconductor device described above.

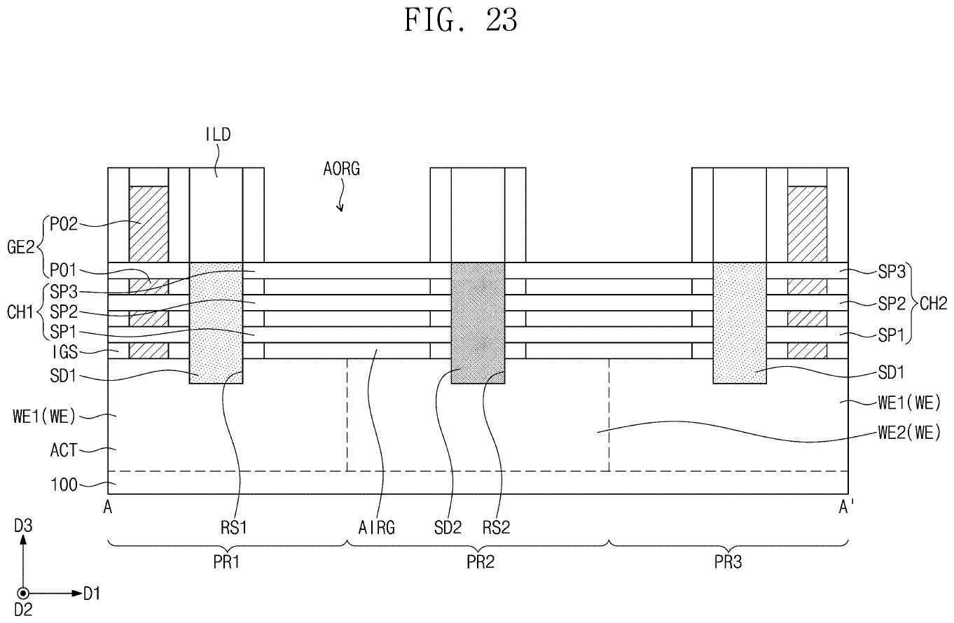

FIG. 23 is a diagram illustrating a method for manufacturing a semiconductor device according to some embodiments of inventive concepts. Specifically, FIG. 23 is a cross-sectional view taken along line A-A′ of FIG. 5.

Referring to FIGS. 5 and 23, after forming the first gate pattern GE1 and the second gate pattern GE2 described with reference to FIGS. 1 and 2, a portion (in other words, a region, of the first gate pattern GE1, overlapping the first semiconductor pattern CH1) of the first gate pattern GE1 may be removed. Accordingly, additional inner regions AIRG may be formed between the first to third semiconductor layers SP1, SP2, and SP3. In addition, an additional outer region AORG may be formed on the third semiconductor layer SP3.

Referring to FIGS. 5 and 6, each of the additional inner regions AIRG (see FIG. 23) and the additional outer region AORG (see FIG. 23) may be filled with an insulating material, and thus the extension region CR and a portion of the gate region GR of the first gate pattern GE1 may be formed.

Thereafter, the semiconductor device described with reference to FIGS. 5 and 6 may be manufactured using the method for manufacturing a semiconductor device described above.

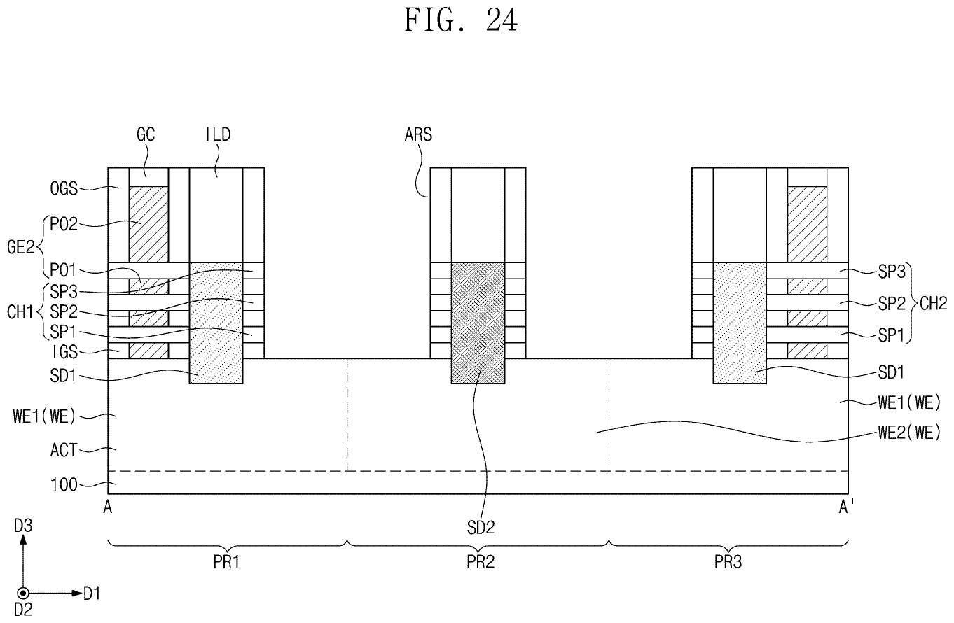

FIG. 24 is a diagram illustrating a method for manufacturing a semiconductor device according to some embodiments of inventive concepts. Specifically, FIG. 24 is a cross-sectional view taken along line A-A′ of FIG. 5.

Referring to FIGS. 5 and 24, after forming the first gate pattern GE1 and the second gate pattern GE2 described with reference to FIGS. 1 and 2, a portion (in other words, a region, of the first gate pattern GE1, overlapping the first semiconductor pattern CH1) of the first gate pattern GE1 may be removed. When the portion of the first gate pattern GE1 is removed, the first semiconductor pattern CH1 may be also removed together. Accordingly, an additional recess ARS may be formed between the first impurity pattern SD1 and the second impurity pattern SD2.

Referring to FIGS. 5 and 7, the inside of the additional recess ARS may be filled with an insulating material, and thus the extension region CR and the portion of the gate region GR of the first gate pattern GE1 may be formed.

Thereafter, the semiconductor device described with reference to FIGS. 5 and 7 may be manufactured using the method for manufacturing a semiconductor device described above.

According to inventive concepts, when a process of removing a stack pattern for forming a recess in which an impurity pattern is formed is performed, the stack pattern covered by an extension region of a first sacrificial pattern may not be removed. Accordingly, another separate recess may not be formed on a boundary between well regions including impurities having different conductive types. As a result, during a process of forming the impurity pattern, another separate impurity pattern may not be unnecessarily formed on the boundary between the well regions. Accordingly, functional degradation of a logic cell caused by an impurity pattern unnecessarily formed may be limited and/or prevented, and electrical characteristics of a semiconductor device may be improved.

The above description of embodiments of inventive concepts provides an example for description of inventive concepts. Therefore, inventive concepts is not limited to the above embodiments, and it is obvious that various modifications and changes such as combining the above embodiments may be made by those skilled in the art within the technical spirit of inventive concepts.

What is claimed is:

1. A semiconductor device comprising:
a first impurity pattern and a second impurity pattern spaced apart from each other in a first direction on a substrate, the first direction being parallel to an upper surface of the substrate, and the first impurity pattern including impurities of a different conductive type than impurities in the second impurity pattern;
a first semiconductor pattern between the first impurity pattern and the second impurity pattern; and
a first gate pattern crossing the first semiconductor pattern, wherein
the first gate pattern includes a gate region extends in a second direction and an extension region extending from the gate region in the first direction, and
the second direction crosses the first direction.

2. The semiconductor device of claim 1, further comprising:
an active pattern including a well region on the substrate, wherein
the well region includes a first well region under the first impurity pattern, and a second well region under the second impurity pattern,
a first portion of the extension region of the first gate pattern is on the first well region, and
a second portion of the extension region of the first gate pattern is on the second well region.

3. The semiconductor device of claim 1, further comprising:
a second semiconductor pattern spaced apart from the first semiconductor pattern with the first impurity pattern therebetween; and
a second gate pattern crossing the second semiconductor pattern, wherein
a width of the first gate pattern in the first direction is greater than a width of the second gate pattern in the first direction.

4. The semiconductor device of claim 1, wherein
the first semiconductor pattern comprises a plurality of semiconductor layers stacked on the substrate,
an inner portion of the extension region of the first gate pattern is between the semiconductor layers, and
an outer portion of the extension region of the first gate pattern is on an uppermost semiconductor layer among the semiconductor layers.

5. The semiconductor device of claim 4, wherein the inner portion of the extension region of the first gate pattern and the outer portion of the extension region of the first gate pattern each comprise a conductive material.

6. The semiconductor device of claim 4, wherein
the inner portion of the extension region of the first gate pattern comprises a semiconductor material, and
the outer portion of the extension region of the first gate pattern comprises a conductive material.

7. The semiconductor device of claim 4, wherein
the inner portion of the extension region of the first gate pattern and the outer portion of the extension region of the first gate pattern each comprise an insulating material, and
the gate region of the first gate pattern comprises an insulating material and a conductive material.

8. The semiconductor device of claim 1, wherein the gate region of the first gate pattern is between the first impurity pattern and the extension region of the first gate pattern.

9. The semiconductor device of claim 1, wherein
the gate region of the first gate pattern comprises a pair of gate regions adjacent to each other in the first direction,
the extension region of the first gate pattern is between the pair of gate regions, and
the gate regions of the first gate pattern are connected to each other through the extension region of the first gate pattern.

10. The semiconductor device of claim 1, wherein in a plan view, the first gate pattern has an H shape.

11. The semiconductor device of claim 1, wherein
a width of the extension region of the first gate pattern in the second direction is less than or equal to a width of the first semiconductor pattern in the second direction.

12. The semiconductor device of claim 1, wherein
a width of the extension region of the first gate pattern in the second direction is smaller than a width of the gate region in the second direction.

13. The semiconductor device of claim 1, wherein
the extension region of the first gate pattern comprises a plurality of extension regions adjacent to each other in the second direction.

14. A semiconductor device comprising:
a first impurity pattern and a second impurity pattern spaced apart from each other in a first direction on a substrate, the first direction being parallel to an upper surface of the substrate, the first impurity pattern including impurities of a different conductive type than impurities in the second impurity pattern;
a first semiconductor pattern between the first impurity pattern and the second impurity pattern; and
a first gate pattern crossing the first semiconductor pattern, wherein
the first gate pattern includes gate regions adjacent to each other in the first direction,
each of the gate regions extends in a second direction,
the second direction crosses the first direction, and
the first gate pattern further includes an extension region between the gate regions of the first gate pattern.

15. The semiconductor device of claim 14, wherein
the extension region of the first gate pattern extends in the first direction, and
the gate regions of the first gate pattern are connected to each other through the extension region.

16. The semiconductor device of claim 14, further comprising:
an active pattern including a well region on the substrate, wherein
the well region includes a first well region under the first impurity pattern and a second well region under the second impurity pattern,
a first portion of the extension region of the first gate pattern is on the first well region, and
a second portion of the extension region of the first gate pattern is on the second well region.

17. The semiconductor device of claim 14, further comprising:
a second semiconductor pattern spaced apart from the first semiconductor pattern with the first impurity pattern therebetween; and
a second gate pattern crossing the second semiconductor pattern,
wherein a width of the first gate pattern in the first direction is greater than a width of the second gate pattern in the first direction.

18. The semiconductor device of claim 14, wherein a width of the extension region of the first gate pattern in the second direction is smaller than widths of the gate regions in the second direction.

19. The semiconductor device of claim 14, wherein
one gate region among the gate regions of the first gate pattern is adjacent to the first impurity pattern, and
an other gate region among the gate regions of the first gate pattern is adjacent to the second impurity pattern.

20. A semiconductor device comprising:
a first impurity pattern and a second impurity pattern spaced apart from each other in a first direction on a substrate, the first direction being parallel to an upper surface of the substrate, and the first impurity pattern including impurities of a different conductive type than impurities in the second impurity pattern;
a first semiconductor pattern between the first impurity pattern and the second impurity pattern;
a second semiconductor pattern spaced apart from the first semiconductor pattern with the first impurity pattern therebetween, each of the first semiconductor pattern and the second semiconductor pattern including a plurality of semiconductor layers stacked on the substrate;
a first gate pattern crossing the first semiconductor pattern;
a second gate pattern crossing the second semiconductor pattern;
an internal gate spacer between the first impurity pattern and the first gate pattern; and
a rear surface active contact under at least one of the first impurity pattern or the second impurity pattern, wherein
the first gate pattern includes gate regions and an extension region between the gate regions,
the gate regions are adjacent to each other in the first direction,
each of the gate regions extends in a second direction, and
the second direction crosses the first direction.
